(19) United States
(12) Patent Application Publication
(10) Pub. No.: US 2024/0096723 A1
(43) Pub. Date: Mar. 21, 2024

(54) SEMICONDUCTOR DEVICE

(71) Applicant: Sumitomo Electric Device Innovations, Inc., Yokohama-shi (JP)

(72) Inventor: Akira SAHASHI, Yokohama-shi (JP)

(73) Assignee: Sumitomo Electric Device Innovations, Inc., Yokohama-shi (JP)

(21) Appl. No.: 18/368,363

(22) Filed: Sep. 14, 2023

(30) Foreign Application Priority Data
Sep. 15, 2022 (JP) 2022-147243

(51) Int. Cl. H01L 23/31; H01L 23/00

(52) U.S. Cl. CPC H01L 23/3142; H01L 23/3121; H01L 24/29; H01L 24/32; H01L 24/48; H01L 24/73; H01L 2224/29111; H01L 2224/29118; H01L 2224/29139; H01L 2224/29144; H01L 2224/29147; H01L 2224/2916; H01L 2224/32245; H01L 2224/48157; H01L 2224/73265

(57) ABSTRACT

A semiconductor device includes a wiring substrate including an opening formed to penetrate from a first main surface to a second main surface, and configured to include an insulating material, a metal substrate fixed to the wiring substrate to cover the opening from the second main surface side, a semiconductor chip fixed inside the opening on a main surface of the metal substrate, a resin disposed to cover the semiconductor chip from above the first main surface on the main surface, and formed of a material having a thermal expansion coefficient different from that of the wiring substrate, and an adhesive containing a metal paste disposed between a side surface of the wiring substrate and the main surface, and the resin, in which the adhesive is disposed on the main surface so that a thickness gradually increases from a center side of the opening to the side surface.

### CROSS-REFERENCE TO RELATED APPLICATION

This application claims priority from Japanese Patent Application No. 2022-147243, filed on Sep. 15, 2022, the entire subject matter of which is incorporated herein by reference.

### TECHNICAL FIELD

The present disclosure relates to a semiconductor device.

### BACKGROUND

Japanese Unexamined Patent Publication No. H9-27563 describes a semiconductor device including a metal substrate, a circuit substrate joined to the metal substrate with an Ag paste therebetween and including an opening, which houses a semiconductor circuit element, provided at a central portion, a bonding wire connecting the semiconductor circuit element and a conductor circuit layer on the circuit substrate, and a potting resin sealing body sealing the semiconductor circuit element and the circuit substrate. According to such a structure of the semiconductor device, workability of mounting the semiconductor circuit element can be improved.

### SUMMARY

A semiconductor device according to one aspect of the present disclosure includes a wiring substrate having a first main surface and a second main surface, including an opening formed to penetrate from the first main surface to the second main surface, and configured to include an insulating material, a metal substrate fixed to the wiring substrate to cover the opening from the second main surface side, a semiconductor chip fixed inside the opening on a main surface of the metal substrate on the wiring substrate side, a resin disposed to cover the semiconductor chip from above the first main surface of the wiring substrate to the inside of the opening on the main surface of the metal substrate, and formed of a material having a thermal expansion coefficient different from that of the wiring substrate, and an adhesive containing a metal paste disposed between a side surface defining the opening of the wiring substrate and the main surface of the metal substrate, and the resin, in which the adhesive is disposed on the main surface of the metal substrate so that a thickness gradually increases from a center side of the opening to the side surface of the wiring substrate.

### BRIEF DESCRIPTION OF THE DRAWINGS

FIG. 1 is a cross-sectional view illustrating a configuration of a semiconductor device according to one embodiment of the present disclosure.

FIG. 2 is a plan view illustrating a main part of the semiconductor device of FIG. 1.

FIG. 3 is a cross-sectional view along line III-III of FIG. 2.

FIG. 4 is a cross-sectional view illustrating a configuration of a semiconductor device according to a comparative example.

FIG. 5 is a plan view illustrating a main part of the semiconductor device of FIG. 4.

FIG. 6 is a cross-sectional view in a thickness direction of a wiring substrate illustrating a state of thermal stress generated in a resin, a wiring substrate, and a metal base in the comparative example.

### DETAILED DESCRIPTION

In a conventional semiconductor device, since a circuit substrate and a resin having different thermal expansion coefficients are disposed on a metal substrate, a thermal stress generated in the resin when a temperature rises may cause a problem. Therefore, it is required to prevent reliability of the semiconductor device from decreasing due to peeling of the resin during reflow.

An objective of the present disclosure is to provide a semiconductor device in which a decrease in reliability during reflow can be prevented.

In order to solve the above-described problems, a semiconductor device according to a first aspect of the present disclosure includes a wiring substrate having a first main surface and a second main surface, including an opening formed to penetrate from the first main surface to the second main surface, and configured to include an insulating material, a metal substrate fixed to the wiring substrate to cover the opening from the second main surface side, a semiconductor chip fixed inside the opening on a main surface of the metal substrate on the wiring substrate side, a resin disposed to cover the semiconductor chip from above the first main surface of the wiring substrate to the inside of the opening on the main surface of the metal substrate, and formed of a material having a thermal expansion coefficient different from that of the wiring substrate, and an adhesive containing a metal paste disposed between a side surface defining the opening of the wiring substrate and the main surface of the metal substrate, and the resin, in which the adhesive is disposed on the main surface of the metal substrate so that a thickness gradually increases from a center side of the opening to the side surface of the wiring substrate.

The first aspect described above is configured such that the semiconductor chip is fixed inside the opening of the wiring substrate on the main surface of the metal substrate, and the semiconductor chip is covered in its entirety from the main surface of the wiring substrate to the inside of the opening on the main surface of the metal substrate by the resin, and is configured such that the adhesive containing a metal paste is disposed between the side surface of the opening of the wiring substrate and the main surface of the metal substrate, and the resin, and a thickness of the adhesive gradually increases from the center side of the opening to the side surface of the opening of the wiring substrate. With such a configuration, a thermal stress generated between the wiring substrate and the resin due to a difference in expansion coefficient between the wiring substrate and the resin during reflow can be dispersed, and a decrease in reliability due to occurrence of peeling of the resin during reflow can be prevented.

According to the semiconductor device according to a second aspect of the present disclosure, in the above-described first aspect, the adhesive may be disposed so that a thickness thereof at the side surface of the wiring substrate in a thickness direction of the wiring substrate is half or more of a thickness of the wiring substrate. In this case, since a contact area between the adhesive and the wiring substrate is secured, a thermal stress generated between the wiring substrate and the resin can be further dispersed, and a decrease in reliability during reflow can be reliably prevented.

Also, according to the semiconductor device according to a third aspect of the present disclosure, in the first or second aspect described above, a thermal expansion coefficient of the wiring substrate may be twice or more a thermal expansion coefficient of the resin. Thus, even if a difference in thermal expansion coefficient is larger between the wiring substrate and the resin, a decrease in reliability due to occurrence of peeling of the resin during reflow can be prevented.

Also, according to the semiconductor device according to a fourth aspect of the present disclosure, in any one of the first to third aspects described above, a line of the adhesive connecting an end point on the side surface of the wiring substrate on the first main surface side and an end point on the main surface of the metal substrate on a center side of the opening may form an angle of 45 degrees or less with respect to the main surface of the metal substrate. With such a configuration, a contact area of the adhesive with the metal substrate is sufficiently large, a sufficient effect of dispersing the thermal stress caused by thermal expansion of the wiring substrate and the resin in the thickness direction of the wiring substrate can be obtained, and a mechanical strength with respect to the thermal expansion of the wiring substrate can be secured. As a result, the reliability of the semiconductor device can be further enhanced.

Also, according to the semiconductor device according to a fifth aspect of the present disclosure, in any one of the first to fourth aspects described above, a metal film formed of a metal material containing any one of gold, silver, copper, iron, zinc, and tin may be provided on the main surface of the metal substrate. In this case, an adhesion strength between the semiconductor chip and the metal substrate can be improved.

Also, the semiconductor device according to a sixth aspect of the present disclosure, in any one of the first to fifth aspects described above, may further include another adhesive different from the adhesive and containing a metal paste inside the opening on the main surface of the metal substrate on the wiring substrate side, in which the adhesive and the another adhesive are spaced apart on the main surface of the metal substrate. With such a configuration, occurrence of a positional deviation of the semiconductor chip in the process of curing the adhesive can be prevented, and a mounting accuracy of the semiconductor chip can be enhanced.

Also, according to the semiconductor device according to a seventh aspect of the present disclosure, in the sixth aspects described above, the adhesive and the another adhesive may be formed of the same material. Even in such a case, a decrease in reliability due to occurrence of peeling of the resin during reflow can be prevented.

Also, according to the semiconductor device according to an eighth aspect of the present disclosure, in the sixth or the seventh aspect described above, the adhesive and the another adhesive may include a metal paste containing any one of gold, silver, copper, nickel, and aluminum. When such a configuration is employed, an adhesion strength between the resin, and the adhesive and the another adhesive can be improved, and a decrease in reliability due to occurrence of peeling of the resin during reflow can be prevented.

Also, according to the semiconductor device according to a ninth aspect of the present disclosure, in any one of the first to eighth aspects described above, the wiring substrate may contain any one of an epoxy-based material, a fluorine-based material, a polyphenylene oxide-based material, and a phenol-based material, and the resin may contain either an epoxy-based material or a silicon-based material. Also in such a configuration, a decrease in reliability due to occurrence of peeling of the resin during reflow can be prevented.

Hereinafter, embodiments of the present disclosure will be described with reference to the drawings. Further, in the description of the drawings, the same elements will be denoted by the same reference signs, and duplicate description thereof will be omitted.

### (Configuration of Semiconductor Device)

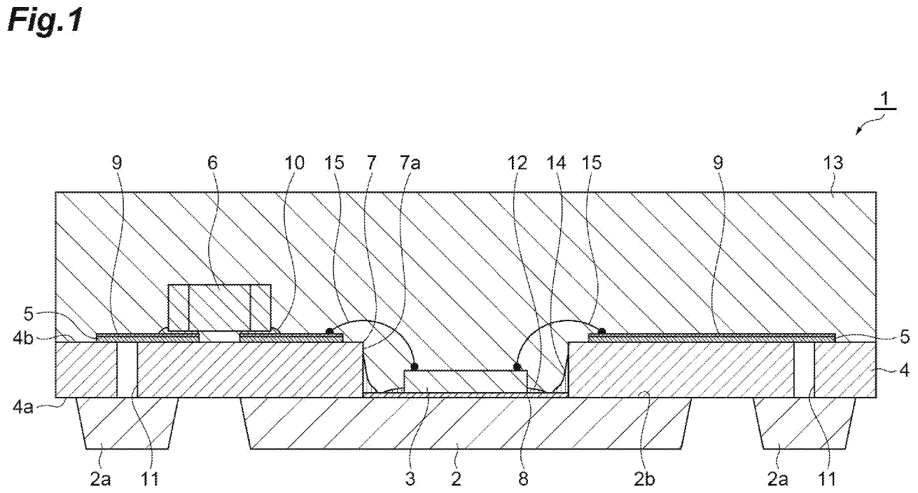

FIG. 1 is a cross-sectional view illustrating a configuration of a semiconductor device 1 according to one embodiment of the present disclosure. The semiconductor device 1 is a semiconductor device incorporated in, for example, a communication module for a wireless base station of a Massive MIMO (Multiple Input Multiple Output) type.

As illustrated in FIG. 1, the semiconductor device 1 includes a metal base (metal substrate) 2, a semiconductor chip 3 mounted on the metal base 2, a wiring substrate 4 overlapped and fixed on the metal base 2, a circuit pattern 5 formed on the wiring substrate 4, a circuit element 6 mounted on the wiring substrate 4 with the circuit pattern 5 therebetween, and a resin 13 for sealing the entire semiconductor device 1. An opening 7 penetrating to the metal base 2 is formed at a central portion of the wiring substrate 4, and the semiconductor chip 3 is disposed inside the opening 7 on the metal base 2.

The metal base 2 is formed of, for example, copper (Cu), an alloy containing copper, aluminum (Al), or an alloy containing iron (Fe), and has a substantially rectangular flat plate shape. A surface and a back surface of the metal base 2 may be plated with gold (Au) or the like to prevent oxidation of the surface and secure conductivity through a metallic bond with a conductive paste. For example, nickel (Ni), palladium (Pd), and gold films may be formed in that order on the metal base 2, and gold plating 8 may be applied thereon. The gold plating 8 is formed at least on the entire inner surface of the opening 7 on a main surface 2b of the metal base 2 on the wiring substrate 4 side. Instead of the gold plating 8, a metal of silver (Ag), copper, iron, zinc (Zn), or tin (Sn) may be used. Also, a connection terminal 2a electrically connected to the circuit pattern 5 on the wiring substrate 4 is formed at an end portion of the metal base 2.

The wiring substrate 4 is configured to include an insulating material such as, for example, an epoxy-based resin material, a fluorine-based resin material, a polyphenylene oxide (PPO)-based resin material, or a phenol-based resin material, and has a substantially rectangular flat plate shape including a main surface (second main surface) 4a on the metal base 2 side and a main surface (first main surface) 4b on a side opposite thereto. The substantially rectangular opening 7 penetrating from the main surface 4b to the main surface 4a is formed in the wiring substrate 4 at a central portion on the main surface 2b of the metal base 2. That is, the metal base 2 is fixed to cover the opening 7 from the main surface 4a side. As a result, a space for mounting the semiconductor chip 3 on the main surface 2b of the metal base 2 is defined by a side surface 7a of the opening 7. Also, the circuit pattern 5 formed of a metal such as copper is provided on the main surface 4b of the wiring substrate 4, and a metal plating 9 such as gold plating is applied on the circuit pattern 5. Also, the circuit element 6, which is a surface-mounted component, is mounted on the circuit pattern 5 on the main surface 4b of the wiring substrate 4. This circuit element 6 is electrically connected to the circuit pattern 5 using a solder 10. Further, a plurality of vias 11 for electrically connecting the connection terminal 2a and the circuit pattern 5 are provided in the wiring substrate 4.

The semiconductor chip 3 is an integrated circuit including, for example, a high electron mobility transistor (HEMT) containing gallium nitride (GaN) as a main component on a silicon carbide (SiC) substrate (not illustrated). The semiconductor chip 3 is adhered and fixed to a central portion inside the opening 7 on the main surface 2b of the metal base 2 with the gold plating 8 therebetween by a first adhesive (another adhesive) 12. A silver paste is used for the first adhesive 12. However, a metal paste containing other metals such as, for example, gold, copper, nickel, or aluminum may be used for the first adhesive 12. Also, instead of being adhered by the first adhesive, the semiconductor chip 3 may be adhered by a eutectic reaction between the gold plating 8 and a substrate of the semiconductor chip 3. Further, the semiconductor chip 3 is electrically connected to the circuit pattern 5 on the wiring substrate 4 by a metal wire 15 such as a gold wire.

The resin 13 is a sealing member disposed to cover the circuit pattern 5, the circuit element 6, and the semiconductor chip 3 from above the main surface 4b of the wiring substrate 4 to the inside of the opening 7 on the main surface 2b of the metal base 2. For example, an epoxy-based resin material is used as the resin 13. However, a silicon-based resin material may be used as the resin 13. A thermal expansion coefficient of the resin 13 is different from a thermal expansion coefficient of the wiring substrate 4, is smaller than the thermal expansion coefficient of the wiring substrate 4, and is preferably half or less of the thermal expansion coefficient of the wiring substrate 4. For example, when an epoxy-based resin material is used as the resin 13, a thermal expansion coefficient in a thickness direction of the resin 13 at a glass-transition point or higher is about 40 [ppm/K], and this is smaller than a thermal expansion coefficient of about 240 [ppm/K] in a thickness direction of the wiring substrate 4 at a glass-transition point or higher when a glass epoxy material is used as the wiring substrate 4. The resin 13 is adhered and disposed from the side surface 7a of the opening 7 to the main surface 2b on the side surface 7a side with a second adhesive (adhesive) 14 interposed therebetween. A silver paste is used for the second adhesive 14. However, a metal paste containing other metals such as, for example, gold, copper, nickel, or aluminum may be used for the second adhesive 14.

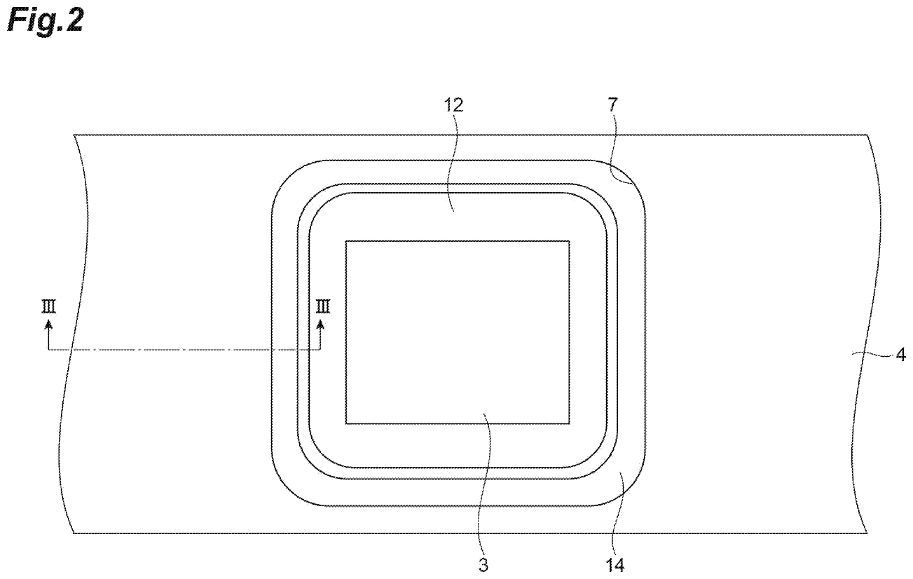

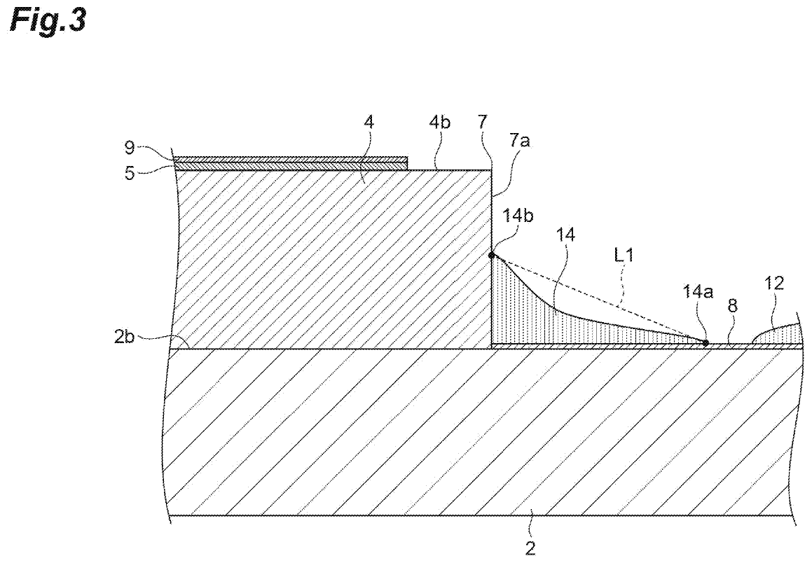

Hereinafter, a disposition state of the first adhesive 12 and the second adhesive 14 on the main surface 2b of the metal base 2 will be described in detail with reference to FIGS. 2 and 3. FIG. 2 is a plan view of a main part of the semiconductor device 1 of FIG. 1, and FIG. 3 is a cross-sectional view along line III-III of FIG. 2.

The first adhesive 12 is disposed to be interposed between the main surface 2b of the metal base 2 and the semiconductor chip 3. An edge portion of the first adhesive 12 in a direction along the main surface 2b is substantially rectangular along the opening 7.

The second adhesive 14 is disposed from the side surface 7a defining the opening 7 to the gold plating 8 on the main surface 2b extending substantially perpendicular to the side surface 7a to be in close contact therewith with a uniform thickness along the opening 7. An edge portion of the second adhesive 14 on the semiconductor chip 3 side in a direction along the main surface 2b has a substantially rectangular shape along the opening 7, and the edge portion thereof is spaced apart at a substantially constant distance from the edge portion of the first adhesive 12 on the main surface 2b by at least 0.1 mm or more. A cross-sectional shape (see, FIG. 3) of the second adhesive 14 in a direction perpendicular to the side surface 7a and the main surface 2b is such that a thickness thereof gradually increases from a center side to the side surface 7a in the space defined by the opening 7, and is curved toward the main surface 2b side. Also, a thickness of the above-described cross-sectional shape at the side surface 7a in a thickness direction of the wiring substrate 4 is half or more of a thickness of the wiring substrate 4. Further, in the above-described cross-sectional shape, a line L1 of the second adhesive 14 connecting an end point 14a on the center side of the space defined by the opening 7 and an end point 14b of the side surface 7a on the main surface 4b side is formed to have an inclination of 45 degrees or less with respect to the main surface 2b. Also, a contact area of the second adhesive 14 with the gold plating 8 on the main surface 2b is preferably made larger than a contact area thereof with the side surface 7a.

The second adhesive 14 with such a configuration is disposed by applying it along the side surface 7a by a dispenser or ink jet printing. The fillet geometry of the second adhesive 14 described above is formed by a surface tension. Here, a meniscus at the side surface formed by the second adhesive 14 is higher than a meniscus at an edge portion of the semiconductor chip 3 formed by the first adhesive 12.

### (Operation and Effects of Semiconductor Device)

According to a configuration of the semiconductor device 1 described above, it is configured such that the semiconductor chip 3 is fixed inside the opening 7 of the wiring substrate 4 on the main surface 2b of the metal base 2 with the first adhesive 12 containing a metal paste, and the semiconductor chip 3 is sealed in its entirety from the main surface 4b of the wiring substrate 4 to the inside of the opening 7 on the main surface 2b of the metal base by the resin 13, and is configured such that the second adhesive 14 containing a metal paste is disposed between the side surface 7a of the opening 7 of the wiring substrate 4 and the main surface 2b of the metal base 2, and the resin 13, and a thickness of the second adhesive 14 gradually increases from the center side of the opening 7 to the side surface 7a of the opening 7 of the wiring substrate 4. With such a configuration, a thermal stress generated between the wiring substrate 4 and the resin 13 due to a difference in expansion coefficient between the wiring substrate 4 and the resin 13 during reflow can be dispersed, and a decrease in reliability due to occurrence of peeling of the resin 13 during reflow can be prevented.

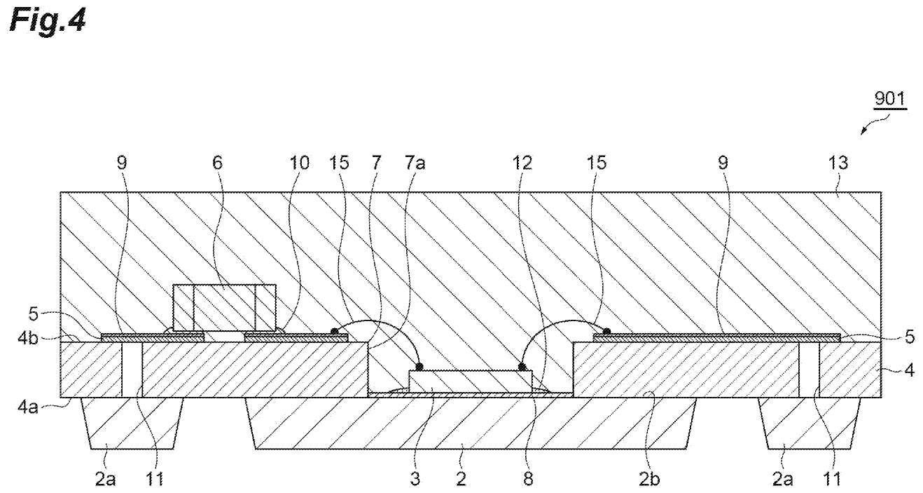

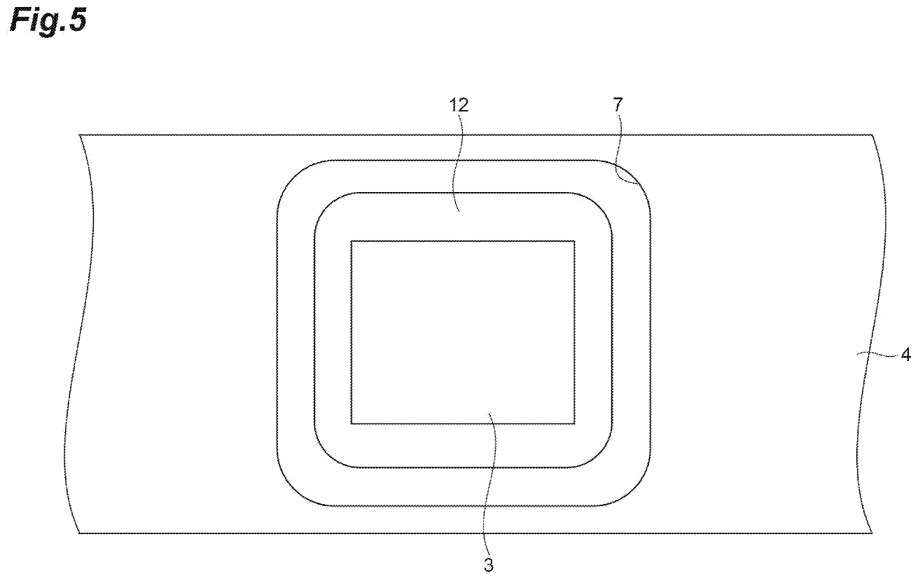

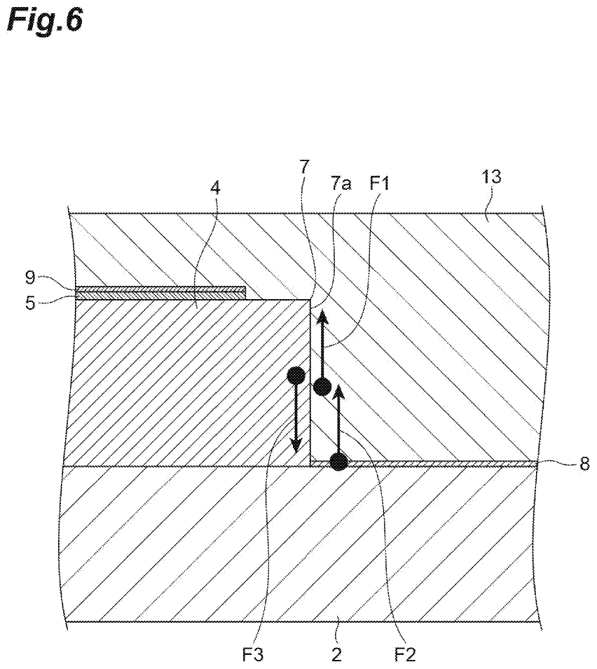

The above-described operation and effects will be described in detail in comparison with a comparative example. FIG. 4 is a cross-sectional view illustrating a configuration of a semiconductor device according to a comparative example, FIG. 5 is a plan view illustrating a main part of the semiconductor device of FIG. 4, and FIG. 6 is a cross-sectional view in a thickness direction of a wiring substrate illustrating a state of thermal stress generated in a resin, the wiring substrate, and a metal base in the comparative example. A semiconductor device 901 according to the comparative example differs from the semiconductor device 1 according to the embodiment in that the second adhesive 14 is not disposed.

In the semiconductor device 901, a thermal stress is generated due to a difference in thermal expansion coefficient between a wiring substrate 4 and a resin 13, and the thermal stress concentrates on an opening 7 of the wiring substrate 4 during reflow (thermal shock). That is, since a thermal expansion coefficient of the wiring substrate 4 is relatively large and a thermal expansion coefficient of the resin 13 is relatively small, a shearing stress F1 that lifts in a direction away from a metal base 2 is generated on the resin 13 side along a side surface 7a, a tensile stress F2 is generated on a surface of a gold plating 8 by the resin 13 being lifted, and a shearing stress F3 is generated in a direction that suppresses thermal expansion on the wiring substrate 4 along the side surface 7a (FIG. 6). Also, the gold plating 8 has a low affinity with the resin 13 in physical properties. Therefore, the thermal stress concentrates in the vicinity of the opening 7 during reflow, and peeling is likely to occur between the gold plating 8 and the resin 13, the peeling progresses to a top of a semiconductor chip 3, and thereby the reliability decreases.

On the other hand, according to a configuration of the semiconductor device 1, the second adhesive 14 is applied and cured in the vicinity of the side surface 7a of the opening 7 on which the thermal stress concentrates, and thereby adhesion of the resin 13 can be improved. That is, since the silver paste is used as the second adhesive 14, the resin adhesion is better than the gold plating 8. Also, an adhesion strength between the second adhesive 14 and the gold plating 8 is also larger than an adhesion strength between the resin 13 and the gold plating 8. Further, concentration of the thermal stress can be alleviated by inclining the side surface 7a on which the stress concentrates with the second adhesive. As a result, in the present embodiment, peeling of the resin 13 from the main surface 2b in the vicinity of the side surface 7a due to concentration of the stress can be effectively prevented.

Also, in the present embodiment, the second adhesive 14 is disposed so that a thickness in the thickness direction of the wiring substrate 4 at the side surface 7a of the wiring substrate 4 is half or more of a thickness of the wiring substrate 4. In this case, since a contact area between the second adhesive 14 and the wiring substrate 4 is secured, an effect of improving the adhesion between the side surface 7a of the wiring substrate 4 and the resin 13 can be sufficiently secured, and a decrease in reliability during reflow can be reliably prevented.

Also, in the present embodiment, the line of the second adhesive 14 connecting the end point 14a and the end point 14b forms an angle of 45 degrees or less with respect to the main surface 2b of the metal base 2. With such a configuration, a contact area of the second adhesive 14 with the metal base 2 is sufficiently large, a sufficient effect of dispersing the thermal stress caused by thermal expansion of the wiring substrate 4 and the resin 13 in the thickness direction of the wiring substrate 4 can be obtained, and a mechanical strength with respect to the thermal expansion of the wiring substrate 4 can be secured. As a result, the reliability of the semiconductor device 1 can be further enhanced.

Also, in the present embodiment, the contact area of the second adhesive 14 with the gold plating 8 is made larger than the contact area with the metal base 2. Thereby, peeling of the resin 13 in the vicinity of the opening 7 can be effectively prevented by dispersing the thermal stress, and the reliability can be further improved.

Also, in the present embodiment, a metal film such as the gold plating 8 is provided on the main surface 2b of the metal base 2. With such a configuration, an adhesion strength between the semiconductor chip 3 and the metal base 2 using the first adhesive 12 can be improved. Also, conductivity between the semiconductor chip 3 and the metal base 2 can be secured. In addition, when a silver paste, for example, is used as the first adhesive 12 and a metal containing copper is used as the metal base 2, if the first adhesive 12 is directly brought into close contact with the metal base 2, the metal base 2 may be oxidized and adhesion therebetween may be lowered, but such a situation can be prevented by interposing the gold plating 8 therebetween.

Also, in the present embodiment, the first adhesive 12 and the second adhesive 14 are spaced apart from each other on the main surface 2b of the metal base 2. With such a configuration, occurrence of a positional deviation of the semiconductor chip 3 when a viscosity of the second adhesive 14 decreases in the process of curing the second adhesive 14 can be prevented, and a mounting accuracy of the semiconductor chip 3 can be enhanced.

Also, in the present embodiment, the second adhesive 14 is uniformly disposed in a direction along the opening 7. Therefore, the thermal stress concentrating on a portion of the side surface 7a of the opening 7 can be prevented, and the reliability of the semiconductor device 1 can be further enhanced.

While principles of the present disclosure have been illustrated and described in the preferred embodiments, it will be recognized by those skilled in the art that the present disclosure may be modified in disposition and detail without departing from such principles. The present disclosure is not limited to the specific configurations disclosed in the present embodiment. Therefore, claims are made for all modifications and changes that arise from the scope of the claims and the spirit thereof.

A metal paste containing a resin may be used as the first adhesive 12 and the second adhesive 14 in the above-described embodiment. In this way, both the adhesion strength between the gold plating 8 on the main surface 2b and the resin 13 and the adhesion strength between the wiring substrate 4 and the resin 13 can be secured, and the reliability of the semiconductor device 1 can be further enhanced.

What is claimed is:

1. A semiconductor device comprising:
a wiring substrate having a first main surface and a second main surface, including an opening formed to penetrate from the first main surface to the second main surface, and configured to include an insulating material;
a metal substrate fixed to the wiring substrate to cover the opening from the second main surface side;
a semiconductor chip fixed inside the opening on a main surface of the metal substrate on the wiring substrate side;
a resin disposed to cover the semiconductor chip from above the first main surface of the wiring substrate to the inside of the opening on the main surface of the metal substrate, and formed of a material having a thermal expansion coefficient different from that of the wiring substrate; and
an adhesive containing a metal paste disposed between a side surface defining the opening of the wiring substrate and the main surface of the metal substrate, and the resin, wherein the adhesive is disposed on the main surface of the metal substrate so that a thickness gradually increases from a center side of the opening to the side surface of the wiring substrate.

2. The semiconductor device according to claim 1, wherein the adhesive is disposed so that a thickness thereof at the side surface of the wiring substrate in a thickness direction of the wiring substrate is half or more of a thickness of the wiring substrate.

3. The semiconductor device according to claim 1, wherein a thermal expansion coefficient of the wiring substrate is twice or more a thermal expansion coefficient of the resin.

4. The semiconductor device according to claim 1, wherein a line of the adhesive connecting an end point on the side surface of the wiring substrate on the first main surface side and an end point on the main surface of the metal substrate on a center side of the opening forms an angle of 45 degrees or less with respect to the main surface of the metal substrate.

5. The semiconductor device according to claim 1, wherein a metal film formed of a metal material containing any one of gold, silver, copper, iron, zinc, and tin is provided on the main surface of the metal substrate.

6. The semiconductor device according to claim 1, further comprising another adhesive different from the adhesive and containing a metal paste inside the opening on the main surface of the metal substrate on the wiring substrate side, wherein
the adhesive and the another adhesive are spaced apart on the main surface of the metal substrate.

7. The semiconductor device according to claim 6, wherein the adhesive and the another adhesive are formed of the same material.

8. The semiconductor device according to claim 6, wherein the adhesive and the another adhesive include a metal paste containing any one of gold, silver, copper, nickel, and aluminum.

9. The semiconductor device according to claim 1, wherein the wiring substrate contains any one of an epoxy-based material, a fluorine-based material, a polyphenylene oxide-based material, and a phenol-based material, and the resin contains either an epoxy-based material or a silicon-based material.

10. The semiconductor device according to claim 6, wherein a meniscus at the side surface formed by the adhesive is higher than a meniscus at an edge portion of the semiconductor chip formed by the another adhesive.
